(19) United States
(12) Patent Application Publication
(10) Pub. No.: US 2008/0130249 A1
(43) Pub. Date: Jun. 5, 2008

(54) COMPLEX MEMORY CHIP, MEMORY CARD HAVING THE SAME, AND METHOD OF MANUFACTURING THE MEMORY CARD

(75) Inventor: Jin-Jun PARK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/951,093

(22) Filed: Dec. 5, 2007

(30) Foreign Application Priority Data
Dec. 5, 2006 (KR) 2006-121862

(51) Int. Cl. H05K 1/14; H04S 1/00

(52) U.S. Cl. 361/737; 361/683; 29/592.1

(57) ABSTRACT

A complex memory chip includes a peripheral circuit block, a memory block for storing data, and a control block for controlling functions of the peripheral circuit block and the memory block. The peripheral circuit block, the memory block and the control block are formed as a single chip. Further, a memory card includes a printed circuit board, the complex memory chip formed on a first face of the printed circuit board, a wire for electrically connecting the complex memory chip to the printed circuit board, a contact pad formed on a second face of the printed circuit board opposite to the first face to be electrically connected to the complex memory chip, and a molding member for fixing the complex memory chip to the printed circuit board.

### CROSS-REFERENCE TO RELATED APPLICATION

This application claims priority under 35 USC §119 to Korean Patent Application No. 2006-121862 filed on Dec. 5, 2006, the contents of which are herein incorporated by reference in their entirety for all purposes.

### BACKGROUND

1. Technical Field

Example embodiments of the present invention relate to a complex memory chip, a memory card having the complex memory chip, and a method of manufacturing the memory card. More particularly, example embodiments of the present invention relate to a complex memory chip that is applicable for a digital device such as a computer, a cellular phone, a digital camera, etc., a memory card having the complex memory chip, and a method of manufacturing the memory card.

2. Description of the Related Art

Recently, as digital devices such as computers, cellular phones, digital cameras, etc., have been rapidly developed, a memory card as a storage medium, which is used as a peripheral device for the digital devices, has also been quickly developed. Particularly, the memory card may have gigabytes of storage capacity.

The memory card may include a printed circuit board (PCB), a peripheral circuit block formed on the PCB, a memory block for storing data, a control block for controlling functions of the above-mentioned elements, etc. Here, each of the peripheral block, the memory block and the control block has a separate chip. That is, the memory card may include a chip for the peripheral circuit block, a chip for the memory block and a chip for the control block. Thus, the memory card may include the separate chips of the peripheral circuit block, the memory block and the control block arranged on the PCB.

An example of a conventional memory card having a structure substantially similar to that of the above-mentioned memory card is disclosed in U.S. Pat. No. 6,943,438.

However, when the conventional memory card includes the separate chips of the peripheral circuit block, the memory block, and the control block arranged on the PCB, the conventional memory card may have a large size. Further, electrical connection lengths between the peripheral circuit block, the memory block, and the control block may be elongated so that the conventional memory card may have a low operational efficiency.

Furthermore, when the conventional memory card is formed by stacking the peripheral circuit block, the memory block, and the control block, the stack type memory card may have a relatively large thickness due to the separate chips of the peripheral circuit block, the memory block and the control block. The present invention addresses these and other disadvantages of the conventional art.

### SUMMARY

Example embodiments of the present invention provide a complex memory chip including a peripheral circuit block, a memory block and a control block. Example embodiments of the present invention also provide a memory card including the above-mentioned complex memory chip. Example embodiments of the present invention further provide a method of manufacturing the above-mentioned memory card.

A complex memory chip in accordance with one aspect of the present invention includes a peripheral circuit block, a memory block for storing data, and a control block for controlling functions of the peripheral circuit block and the memory block. The peripheral circuit block, the memory block and the control block are formed as a single chip.

According to the present invention, the complex memory chip may have a single chip in which the peripheral circuit block, the memory block for storing the data and the control block for controlling the functions of the peripheral circuit block and the memory block are integrated. Further, the complex memory chip is applicable for a memory card. Therefore, the memory card may have a size much smaller than that of the conventional memory card on which the separate chips of the peripheral circuit block, the memory block and the control block are arranged. Further, electrical connection lengths between the peripheral circuit block, the memory block and the control block may be significantly shortened so that the memory card may have an improved operational efficiency.

### BRIEF DESCRIPTION OF THE DRAWINGS

The above and other features and advantages of the invention will become readily apparent by reference to the following detailed description when considered in conjunction with the accompanying drawings wherein:

FIG. 1 is a plan view illustrating a complex memory chip in accordance with a first example embodiment of the present invention;

FIG. 2 is a cross-sectional view illustrating a memory card in accordance with a second example embodiment of the present invention;

FIG. 3 is a cross-sectional view illustrating a memory card in accordance with a third example embodiment of the present invention; and

FIGS. 4A to 4C are cross-sectional views illustrating a method of manufacturing the memory card of FIG. 3.

### DETAILED DESCRIPTION

The present invention is described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Embodiment 1

FIG. 1 is a plan view illustrating a complex memory chip in accordance with a first example embodiment of the present invention.

Referring to FIG. 1, a complex memory chip 100 of this example embodiment has a single chip structure. The complex memory chip 100 having the single chip structure includes a peripheral circuit block 11, a memory block 13 for storing data, and a control block 15 for controlling functions of the peripheral circuit block 11 and the memory block 13. In this example embodiment an example of the peripheral circuit block 11 may include a metal wiring, an example of the memory block 13 may include a flash memory, and an example of the control block 15 may include a microprocessor.

Further, the complex memory chip 100 may include an interface block 17 arranged between the peripheral circuit block 11, the memory block 13 and the control block 15 to interface the peripheral circuit block 11, the memory block 13 and the control block 15. In this example embodiment, the interface block 17 may have a single chip structure. Therefore, the complex memory chip 100 having the single chip structure includes the peripheral circuit block 11, the memory block 13, the control block 15 and the interface block 17.

Here, each of the peripheral circuit block 11, the memory block 13, the control block 15 and the interface block 17 has a circuit structure, not a chip structure. That is, the peripheral circuit block 11, the memory block 13, the control block 15 and the interface block 17 are arranged as circuits in a single chip. The circuit arrangement of the peripheral circuit block 11, the memory block 13, the control block 15 and the interface block 17 may be achieved by a design alteration.

Further, the control block 15 may have functions compatible with other digital devices. In this example embodiment, the control block 15 of the complex memory chip 100 may have a circuit structure compatible with digital devices having different functions such as a cellular phone, a computer, a digital camera, etc.

According to this example embodiment, when the complex memory chip 100 is applied to a memory card (as described below), the memory card may have a sufficiently reduced size owing to the complex memory chip 100 having the single chip structure. Further, the memory card may be compatible with digital devices having different functions such as a cellular phone, a computer, a digital camera, etc. Furthermore, since the peripheral circuit block 11, the memory block 13, the control block 15 and the interface block 17 in the complex memory chip 100 are connected to each other in circuit form, the electrical connection lengths between the peripheral circuit block 11, the memory block 13, the control block 15 and the interface block 17 may be significantly shortened. As a result, the memory card may have an improved operational efficiency.

### Embodiment 2

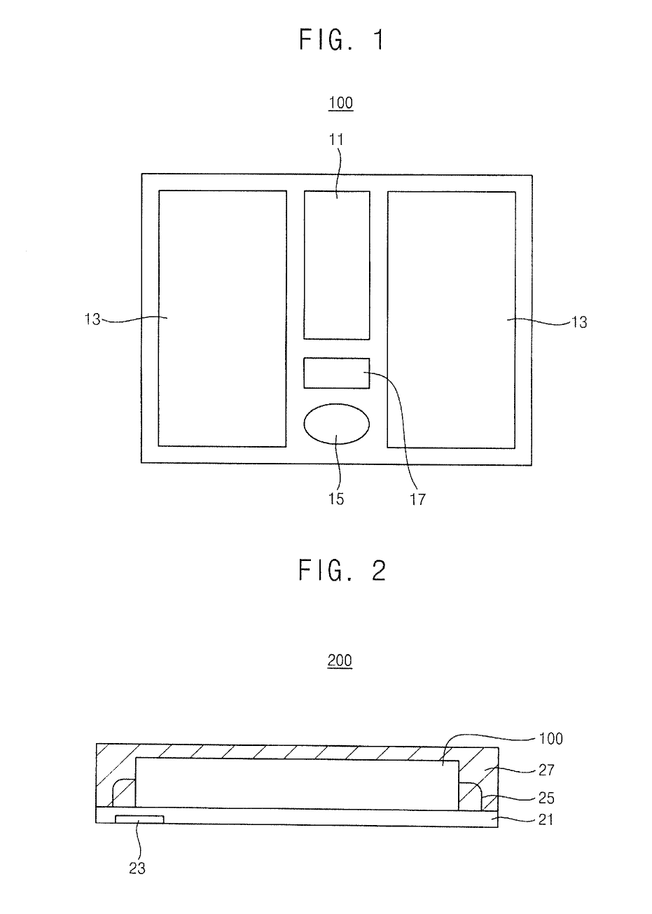

FIG. 2 is a cross-sectional view illustrating a memory card in accordance with a second example embodiment of the present invention.

Referring to FIG. 2, a memory card 200 of this example embodiment includes a printed circuit board (PCB) 21, a complex memory chip 100, a wire 25, a contact pad 23 and a molding member 27.

The PCB 21 has a printed circuit structure on a first face of the PCB 21 or the first face and a second face of the PCB 21 opposite to the first face corresponding to the memory card 200. The complex memory chip 100 is mounted on the first face of the PCB 21. Here, the complex memory chip 100 includes elements substantially the same as those of the complex memory chip 100 in Embodiment 1. Thus, the same reference numerals refer to the same elements and any further description with respect to the same elements are omitted herein for brevity.

The contact pad 23 is formed on the second face of the PCB 21. The contact pad 23 is electrically connected to the complex memory chip 100. In this example embodiment, the electrical connection between the complex memory chip 100 and the contact pad 23 may be achieved by the printed circuit structure of the PCB 21.

The wire 25 connects the PCB 21 to the complex memory chip 100. In this example embodiment, the complex memory chip 100 is stacked on the PCB 21. Thus, the stack type complex memory chip 100 is electrically connected to the PCB 21 using the wire 25.

The molding member 27 secures the complex memory chip 100 to the PCB 21. The molding member 27 supports the wire 25 as well as the complex memory chip 100. In this example embodiment, the molding member 27 may include epoxy resin.

As mentioned above, the memory card 200 of this example embodiment includes the complex memory chip 100 having the single chip structure in which the peripheral circuit block 11, the memory block 13, the control block 15 and the interface block 17 are arranged. Here, the peripheral circuit block 11, the memory block 13, the control block 15 and the interface block 17 in the complex memory chip 100 are arranged in circuit form. Further, the control block 15 of the complex memory chip 100 in the memory card 200 has a circuit structure compatible with digital devices having various functions such as a cellular phone, computer, digital camera, etc.

According to this example embodiment, the memory card 200 may have a sufficiently reduced size. Further, the memory card 200 may be compatible with digital devices having different functions. Furthermore, since the electrical connection lengths in the complex memory chip 100 of the memory card 200 may be sufficiently shortened, the memory card 200 may have an improved operational efficiency.

### Embodiment 3

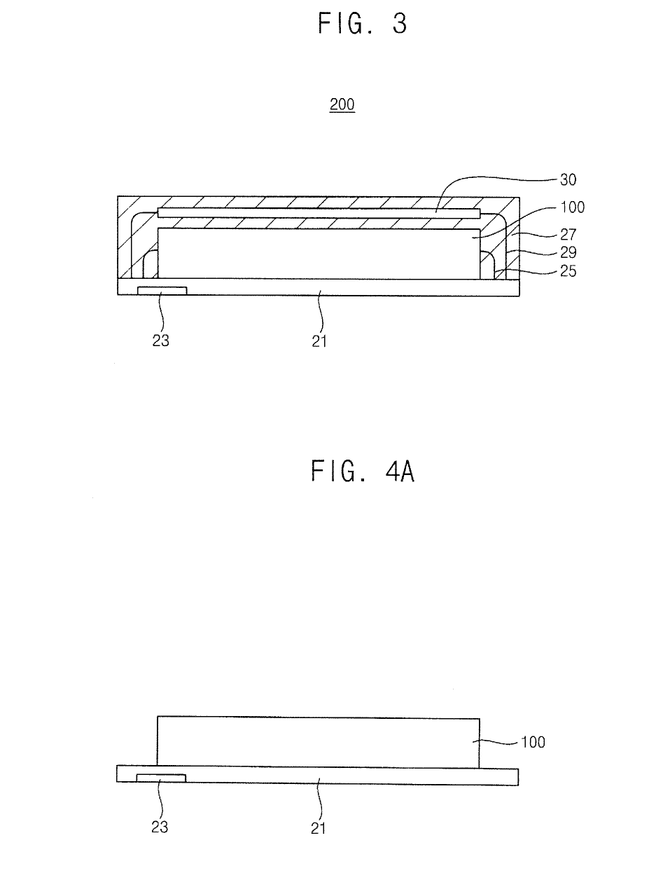

FIG. 3 is a cross-sectional view illustrating a memory card in accordance with a third example embodiment of the present invention.

A memory card 200 of this example embodiment further includes elements 30 such as a plurality of the complex memory chips 100, general memory chips, and passive components, for example: a capacitor, resistance, etc., as well as elements substantially the same as those of the memory card 200 in Embodiment 2. Therefore, the reference numerals refer to the same elements and any further description with respect to the same elements are omitted herein for brevity.

Referring to FIG. 3, when the memory card 200 includes the elements 30 such as a plurality of the complex memory chips 100, the general memory chips and the passive components, the plurality of the complex memory chips 100, the general memory chips and the passive elements are stacked. The memory card 200 may also include a wire 29 electrically connecting elements 30 to the PCB 21.

For example, to increase the memory capacity of the memory card 200, the memory card 200 additionally includes the general memory chips. Further, the complex memory chip 100 and the general memory chip, as the element 30, are stacked.

To apply the memory card 200 to other digital devices, the memory card 200 additionally includes a plurality of the complex memory chips 100. Further, the complex memory chip 100 and other complex memory chips, as the element 30, are stacked.

To improve the electrical operational efficiency of the memory card, the memory card 200 additionally includes passive components. Further, the complex memory chip 100 and the passive components, as the element 30, are stacked.

In this example embodiment, the memory chip, a plurality of the complex memory chips 100 and the passive components in the memory card 200 may be correlated with each other, not separated from each other. Further, when the memory chip, a plurality of the complex memory chips 100 and the passive components such as the element 30 may be correlated with each other, the memory chip, the complex memory chips 100 and the passive components may be stacked.

According to this example embodiment, the memory card 200 may additionally include the memory chip, a plurality of the complex memory chips 100 and the passive components as the element 30. Further, the memory chip, a plurality of the complex memory chips 100 and the passive components are stacked in the memory card 200. Thus, possible applications of the memory card 200 may be increased.

Hereinafter, a method of manufacturing the memory card in FIG. 3 will be illustrated in detail with reference to drawings.

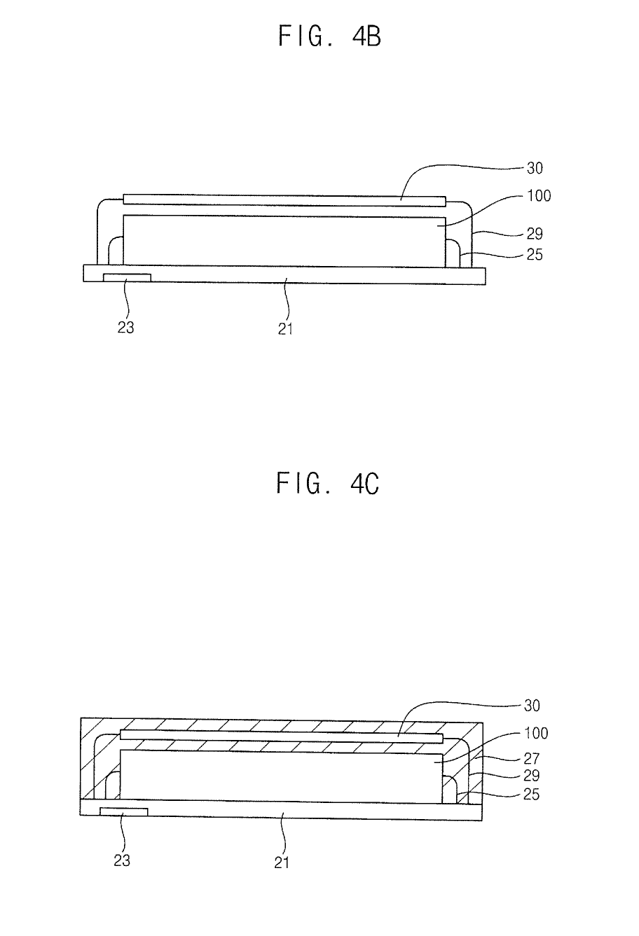

FIGS. 4A to 4C are cross-sectional views illustrating a method of manufacturing the memory card of FIG. 3. Here, the same reference numerals in FIGS. 4A to 4C refer to the same elements of the memory card in FIG. 3.

Referring to FIG. 4A, the PCB 21 is prepared. In this example embodiment, the PCB 21 has a printed circuit structure on a first face of the PCB 21 or the first face and a second face of the PCB 21 opposite to the first face corresponding to the memory card 200. The contact pad 23 is formed on the second face of the PCB 21. Here, the contact pad 23 may be formed concurrently with the preparation of the PCB 21. Further, when the contact pad 23 is formed concurrently with the PCB 21, the contact pad 23 may be easily formed.

The complex memory chip 100 is then stacked on the first face of the PCB 21. In this example embodiment, the complex memory chip 100 may be stacked on the first face of the PCB 21 using an adhesive.

Further, the method of manufacturing the memory card may additionally include forming the element 30 such as the memory chip, a plurality of the complex memory chips 100, the passive components, etc. Therefore, hereinafter, the method of manufacturing the memory card 200 that includes the element 30 such as the memory chip, a plurality of the complex memory chips 100, the passive components, etc., is illustrated in detail.

Referring to FIG. 4B, after stacking the complex memory chip 100 on the first face of the PCB 21, the memory chip, a plurality of the complex memory chips 100, and/or the passive components, as the element 30, are stacked on the complex memory chip 100. Here, the stack sequence of the complex memory chip 100 and the element 30 is exemplarily illustrated. Thus, a reverse sequence of the complex memory chip 100 and the element 30 may be possible. That is, the element 30 may be stacked on the PCB 21 before the complex memory chip 100 is stacked on the PCB 21. The complex memory chip 100 is then stacked on the element 30. Further, the element 30 may include at least two among the memory chip, a plurality of the complex memory chips 100, and the passive components, and the stack arrangement of the element 30 may be arbitrarily selected for manufacturing convenience, operational performance, etc. The element 30 may be electrically connected to the PCB 21 by a wire 29.

The complex memory chip 100 and the PCB 21 are electrically connected to each other using the wire 25. When the memory card includes the element 30, the element 30 and the PCB 21 may be electrically connected to each other using the wire 29.

Referring to FIG. 4C, After stacking the complex memory chip 100 and the element 30 on the PCB 21, and then electrically connecting the complex memory chip 100 and the element 30 to the PCB 21 using the wires 25 and 29, the complex memory chip 100 and the element 30 are molded using the molding member 27, such as epoxy resin. Simultaneously, the wires 25 and 29 are molded. The complex memory chip 100 and the element 30 are molded using the molding member 27 so that the complex memory chip 100 and the element 30 are firmly secured to the PCB 21.

According to this example embodiment, the memory card including the complex memory chip 100 that has the single circuit structure in which the peripheral circuit block, the memory block, the control block and the interface block are arranged in circuit form may be readily manufactured.

According to the present invention, the peripheral circuit block, the memory block, the control block and the interface block are arranged in circuit form in the single chip of the complex memory chip. Further, the complex memory chip is applied to the memory card.

Therefore, the memory card of the present invention may have a sufficiently reduced area. Further, the memory card may be compatible with various digital devices.

As a result, when the complex memory chip, the memory card and the method of manufacturing the memory card is applied to related industries, the present invention may comply with recent memory card applications requiring a small size and diverse functions.

A complex memory chip in accordance with one aspect of the present invention includes a peripheral circuit block, a memory block for storing data, and a control block for controlling functions of the peripheral circuit block and the memory block. The peripheral circuit block, the memory block and the control block are formed as a single chip. In other words, the peripheral circuit block, the memory block, and the control block are fabricated on a single semiconductor substrate. The semiconductor chip including the peripheral circuit block, the memory block, and the control block, may be referred to as a monolithic integrated circuit.

According to one example embodiment, the control block may have a function compatible with other digital devices. Further, the complex memory chip may include an interface block for interfacing the peripheral circuit block, the memory block and the control block.

A memory card in accordance with another aspect of the present invention includes a printed circuit board, a complex memory chip formed on a first face of the printed circuit board, a wire for electrically connecting the complex memory chip to the printed circuit board, a contact pad formed on a second face of the printed circuit board opposite to the first face to be electrically connected to the complex memory chip, and a molding member for fixing the complex memory chip to the printed circuit board. The complex memory chip includes a peripheral circuit block, a memory block for storing data, and a control block for controlling functions of the peripheral circuit block and the memory block. Further, the peripheral circuit block, the memory block and the control block are formed as a single chip.

According to one example embodiment, the control block may have a function compatible with other digital devices. The memory card may include a plurality of the complex memory chips. In this case, the complex memory chips may be stacked. Further, the memory card may include passive components. In this case, the passive components may be stacked. Furthermore, the complex memory chip may include an interface block for interfacing the peripheral circuit block, the memory block and the control block.

In a method of manufacturing a memory card device in accordance with still another aspect of the present invention, a contact pad is formed on a first face of a printed circuit board. A complex memory chip is then formed on a second face of the printed circuit board opposite to the first face. Here, the complex memory chip includes a peripheral circuit block, a memory block for storing data, and a control block for controlling functions of the peripheral circuit block and the memory block. Further, the peripheral circuit block, the memory block and the control block are formed as a single chip. The printed circuit board and the complex memory chip are electrically connected to each other using a wire. The complex memory chip is molded to secure the complex memory chip to the printed circuit board.

According to one example embodiment, the memory card may include a plurality of the complex memory chips. In this case, the complex memory chips may be stacked. Further, the memory card may include passive components. In this case, the passive components may be stacked.

According to the present invention, the complex memory chip may have the single chip in which the peripheral circuit block, the memory block for storing the data and the control block for controlling the functions of the peripheral circuit block and the memory block are integrated. Further, the complex memory chip is applicable for a memory card. Therefore, the memory card may have a size much smaller than that of the conventional memory card on which the separate chips of the peripheral circuit block, the memory block and the control block are arranged. Further, electrical connection lengths between the peripheral circuit block, the memory block and the control block may be significantly shortened so that the memory card nay have an improved operational efficiency.

Having described the preferred embodiments of the present invention, it is noted that modifications and variations can be made by persons skilled in the art in light of the above teachings. It is therefore to be understood that changes may be made in the particular embodiments of the present invention disclosed which are within the scope and the spirit of the invention as outlined by the appended claims.

What is claimed is:

1. A complex memory chip comprising:
a peripheral circuit block;
a memory block configured to store data; and
a control block configured to control functions of the peripheral circuit block and the memory block,
wherein the peripheral circuit block, the memory block and the control block are formed as a single chip.

2. The complex memory chip of claim 1, wherein the control block has functions compatible with different digital devices.

3. The complex memory chip of claim 1, further comprising an interface block arranged between the peripheral circuit block, the memory block and the control block to interface the peripheral circuit block, the memory block and the control block.

4. A memory card comprising:
a printed circuit board;
a complex memory chip disposed on a first face of the printed circuit board, the complex memory chip including a peripheral circuit block, a memory block configured to store data, and a control block configured to control functions of the peripheral circuit block and the memory block, and the peripheral circuit block, the memory block and the control block being formed as a single chip;
a wire for electrically connecting the complex memory chip to the printed circuit board;
a contact pad disposed on a second face of the printed circuit board opposite to the first face; and
a molding member for securing the complex memory chip to the printed circuit board.

5. The memory card of claim 4, wherein the control block has functions compatible with different digital devices.

6. The memory card of claim 4, further comprising stacked additional complex memory chips that have a structure substantially the same as that of the complex memory chip.

7. The memory card of claim 4, further comprising stacked passive components.

8. The memory card of claim 4, further comprising an interface block arranged between the peripheral circuit block, the memory block and the control block to interface the peripheral circuit block, the memory block and the control block.

9. A method of manufacturing a memory card, comprising:
providing a printed circuit board having a first face, a second face opposite to the first face, and a contact pad formed on the second face;
forming a complex memory chip on the first face of the printed circuit board, the complex memory chip including a peripheral circuit block, a memory block configured to store data, and a control block configured to control functions of the peripheral circuit block and the memory block, wherein the peripheral circuit block, the memory block and the control block are formed as a single chip;
electrically connecting the complex memory chip to the printed circuit board; and
forming a molding member on the complex memory chip to secure the complex memory chip to the printed circuit board.

10. The method of claim 9, further comprising stacking additional complex memory chips that have a structure substantially the same as that of the complex memory chip on the printed circuit board.

11. The method of claim 10, further comprising electrically connecting the additional complex memory chips to the printed circuit board using a wire.

12. The method of claim 9, further comprising stacking passive components on the printed circuit board.

13. The method of claim 12, wherein the passive components are stacked on the printed circuit board and the complex memory chip is stacked on the passive components.

14. The method of claim 12, further comprising electrically connecting the passive components to the printed circuit board using a wire.

15. The method of claim 9, wherein electrically connecting the complex memory chip to the printed circuit board comprises using a wire.
